(19) United States
(12) Patent Application Publication
(10) Pub. No.: US 2024/0351941 A1
(43) Pub. Date: Oct. 24, 2024

(54) METHOD OF PRODUCING A COATED GLASS ARTICLE

(71) Applicant: Pilkington Group Limited, Lathom (GB)

(72) Inventors: Srikanth VARANASI, Ottawa Hills, OH (US); Michael REMINGTON, Toledo, OH (US)

(73) Assignee: Pilkington Group Limited, Lathom (GB)

(21) Appl. No.: 18/684,890

(22) PCT Filed: Aug. 25, 2022
(86) PCT No.: PCT/GB2022/052186

§ 371 Date: Feb. 20, 2024

Related U.S. Application Data
(60) Provisional application No. 63/237,261, filed on Aug. 26, 2021.

(51) Int. Cl. C03C 17/245; C03C 17/34; C23C 16/40

(52) U.S. Cl. CPC C03C 17/245; C03C 17/3417; C23C 16/402; C23C 16/405; C23C 16/407; C03C 2217/228; C03C 2218/1525

(57) ABSTRACT

The presently described subject matter relates to an atmospheric chemical vapor deposition process for depositing a hafnium-containing coating on a glass substrate by reacting a precursor gas mixture containing an organohafnium compound, molecular oxygen, and an olefinic hydrocarbon. Glass articles having a hafnium-containing layer formed on the glass substrate are also provided.

### BACKGROUND OF THE INVENTION

Glass is an article produced when viscous molten material cools rapidly to below its glass transition temperature, without sufficient time for a regular crystal lattice form. Commonly, the glass article is formed of a silica-based material, which may comprise about 70-72 weight % of silicon dioxide (SiO₂). It is known to use the glass articles in architectural and building products such as a transparent material for windows, as internal glazed partitions and as architectural features. In addition to interior and exterior use, the glass articles may be employed as windscreens in various types of vehicles. Additionally, the glass articles may be commonly employed as different optical devices such as lenses and protective shields of different electronic equipment both in consumer, scientific and military use.

A coating may be deposited on conventional glass articles to enhance properties such as thermal conductivity, resistivity, radiation protection, anti-reflectiveness, and the like, for example. Such coatings are conducted in batch-wise processes in high-vacuum conditions and with long processing times.

Accordingly, it would be desirable to form hafnium-containing coatings at essentially atmospheric pressure and to produce them at deposition rates compatible with time-critical manufacturing processes, for example, production of flat glass by a float method, in order to produce affordable coatings for optical thin film stack designs.

### SUMMARY OF THE INVENTION

In concordance and agreement with the present disclosure, an atmospheric CVD process for depositing a hafnium-containing coating on a glass substrate, using a precursor gas mixture comprising an organohafnium compound and an olefinic hydrocarbon, has surprisingly been discovered.

This presently described subject matter is directed to a process for depositing hafnium-containing coatings on a flat glass substrate. More particularly, this presently described subject matter is directed to an atmospheric chemical vapor deposition (CVD) process for producing hafnium-containing coatings at high growth rates on flat glass using a precursor gas mixture comprising an organohafnium compound and an olefinic hydrocarbon.

In one embodiment, a method of forming a coated glass article, comprises: providing a glass substrate; and depositing a hafnium-containing coating on the glass substrate using a chemical vapor deposition process, wherein the chemical vapor deposition process utilizes a precursor gas mixture comprising an organohafnium compound, molecular oxygen, and an olefinic hydrocarbon, wherein the precursor gas mixture is introduced into a vapor space above the glass substrate, wherein the organohafnium compound and the olefinic hydrocarbon react to produce the hafnium-containing coating on the glass substrate, wherein the hafnium-containing coating exhibits a refractive index between about 1.7 and 1.9.

In another embodiment, a chemical vapor deposition process for depositing a coating on a moving glass substrate, comprises: providing a uniform precursor gas mixture comprising a organohafnium compound, molecular oxygen, and an olefinic hydrocarbon, each of the organohafnium compound and the olefinic hydrocarbon having a respective thermal decomposition temperature; delivering the precursor gas mixture at a temperature below the respective thermal decomposition temperatures of the organohafnium compound and the olefinic hydrocarbon to a location adjacent the moving glass substrate to be coated, the moving glass substrate being at a temperature above the thermal decomposition temperature of the organic hafnium compound and surrounded by an atmosphere having a pressure at about atmospheric pressure; and introducing the precursor gas mixture into a vapor space above the moving glass substrate wherein the organohafnium compound and the olefinic hydrocarbon react to produce the coating on the glass substrate, wherein the coating is a hafnium-containing coating exhibiting a refractive index between about 1.7 and 1.9.

In certain embodiments, the organohafnium compound is a hafnium amido compound.

In certain embodiments, the hafnium amido compound comprises a tetrakisdialkylamido hafnium, Hf(NMe₂)₄.

In certain embodiments, the organohafnium compound comprises a tetrakisdialkylamido hafnium compound of a form Hf(NR¹R²)₄ where R¹ and R² are hydrocarbons having 1, 2, or 6 carbon atoms.

In certain embodiments, the hafnium-containing coating has a thickness of at least 50 Angstroms.

In certain embodiments, the precursor gas mixture further comprises helium.

In certain embodiments, a temperature of the glass substrate is at least 400° C., more preferably 425° C., when the precursor gas mixture is introduced during the chemical vapor deposition process.

In certain embodiments, a temperature of the glass substrate is between 425° C. and 700° C., more preferably between 450° C. and 700° C., when the precursor gas mixture is introduced during the chemical vapor deposition process.

In certain embodiments, the olefinic hydrocarbon is at least one of ethylene, propylene, and butene. In certain preferred embodiments, the olefinic hydrocarbon is ethylene.

In certain embodiments, the hafnium-containing coating is a hafnium oxide coating.

In certain embodiments, the glass substrate comprises soda-lime-silica glass.

In certain embodiments, the glass substrate is formed by a float glass process.

In certain embodiments, the hafnium-containing coating is deposited on the glass substrate at a deposition rate of at least 50 Angstroms per second.

In certain embodiments, the coated glass article exhibits between about 0.09% to about 0.54% haze.

In certain embodiments, the coated glass article exhibits between about 56% to about 91% visible light transmission.

In certain embodiments, the coated glass article exhibits between about 8% to about 23% film-side reflectance.

In certain embodiments, the method further comprises depositing a silicon dioxide layer between the glass substrate and the hafnium-containing coating.

In certain embodiments, the silicon dioxide layer has a thickness of at least 200 Angstroms.

In certain embodiments, the method further comprises depositing a tin oxide layer between the glass substrate and the silicon dioxide layer.

In certain embodiments, a temperature of the glass substrate is at least 400° C., more preferably 425° C., when the precursor gas mixture is introduced into the vapor space above the moving glass substrate.

In certain embodiments, a temperature of the glass substrate is between 425° C. and 700° C., more preferably between 450° C. and 700° C., when the precursor gas mixture is introduced into the vapor space above the moving glass substrate.

In certain embodiments, the chemical vapor deposition process further comprises depositing a silicon dioxide layer between the moving glass substrate and the hafnium- containing coating.

In certain embodiments, the chemical vapor deposition process further comprises depositing a tin oxide layer between the moving glass substrate and the silicon dioxide layer.

In accordance with the presently described subject matter, hafnium-containing coated glass articles are also provided. In an embodiment, the hafnium-containing coated glass article comprises a glass substrate having a surface. The glass article further comprises a silicon dioxide layer formed on the surface of the glass substrate and a hafnium-containing layer formed on the silicon dioxide layer.

### DETAILED DESCRIPTION OF THE INVENTION

It is to be understood that the presently described subject matter may assume various alternative orientations and step sequences, except where expressly specified to the contrary. It is also to be understood that the specific devices and processes described in the following specification are simply exemplary embodiments of the inventive concepts defined in the appended claims. Hence, specific dimensions, directions, flow rates, or other physical characteristics relating to the embodiments disclosed are not to be considered as limiting, unless the claims expressly state otherwise. Additionally, although the presently described subject matter will be described in connection with a float glass process, it would be understood by one of ordinary skill in the art that the coating process described herein has applications to other production processes used to deposit hafnium-containing coatings. In the presently described subject matter, “hafnium-containing coatings” means hafnium oxide coatings, hafnium nitride coatings, or hafnium oxynitride coatings.

The process of the presently described subject matter is generally practiced in connection with the formation of a continuous glass ribbon substrate, for example during float glass manufacturing/production. The presently described subject matter permits the production of hafnium-containing coatings deposited on the glass ribbon at a high deposition rate, preferably over 50 Angstroms per second and more preferably over 75 Angstroms per second. It should be appreciated, however, that the deposition rate may be any suitable deposition rate as desired.

High deposition rates are important when coating substrates in manufacturing. This is particularly true for float glass manufacturing where the glass ribbon is traveling at a specific line speed and where a specific coating thickness is required. For obtaining high deposition rates, at least one olefinic hydrocarbon may be used in combination with at least one organohafnium precursor compound to form a hafnium-containing coating without requiring the purposeful addition of water vapor, gaseous oxygen, or other oxygen containing compounds. The deposition rates obtained with the preferred embodiments of the presently described subject matter may be greater than or equal to 1.5 times the deposition rates of other known processes for depositing hafnium-containing coatings.

Organohafnium compounds suitable for use in connection with the presently described subject matter are preferably hafnium amido compounds of the general form Hf(NR¹R²)₄ where N is one of ethyl, methyl, propyl, butyl and phenyl and R¹ and R² are the same or different and can be one of an alkyl group having 1-6 carbon atoms, or other groups such as phenyl, tolyl and the like. Preferred hafnium amido compounds are tetrakisdialkyl amido hafnium compounds. A particularly preferred precursor material is tetrakisdimethyl amido hafnium, Hf(NMe₂)₄.

However, the presently described subject matter is not limited to only hafnium amido compounds, other organohafnium compounds can be used in practicing the presently described subject matter. For example, bis(methylcyclopentadienyl)dimethylhafium, Hf[C₅H₄(CH₃)]₂(CH₃)₂, and bis(methylcyclopentadienyl)methoxymethylhafnium, Hf[C₅H₄(CH₃)]₂(OCH₃)CH₃ may also be used to form the hafnium-containing coating.

It has been found that olefinic hydrocarbons may be used in combination with organohafnium compounds to form hafnium-containing coatings without requiring the purposeful addition of water vapor, gaseous oxygen or other oxygen containing compounds. Olefinic hydrocarbons useful as precursor materials in connection with the presently described subject matter contain one or more double bonds. Preferred olefinic hydrocarbons for use in the practice of the presently described subject matter include ethylene, propylene and butene. A particularly preferred olefinic hydrocarbon is ethylene.

While it is contemplated that the precursor gases could be combined at, or very near, the surface of the glass substrate, the presently described subject matter involves the preparation of a precursor gas mixture. The precursor gas mixture comprises the organohafnium compound and the olefinic hydrocarbon. The precursor gas mixture may further preferably comprise a carrier gas or diluents. The carrier gas may comprise one or a combination of gases. Gases which may comprise the carrier gas include nitrogen, argon, and/or helium. For example, in one embodiment the carrier gas comprises helium. In another embodiment, the carrier gas comprises nitrogen and helium. It should be appreciated that any suitable gas or a combination of suitable gases may be used as the carrier gas. Regardless of the specific constituents, since the precursor gas mixture is comprised of more than one gas, the precursor gas is preferably premixed so that the gas mixture is substantially uniform prior to forming the hafnium-containing coating.

Thermal decomposition of the organohafnium compound and the olefinic hydrocarbon may initiate the hafnium containing coating deposition reaction at a high rate. Thus, before deposition is desired, the precursor gas mixture is maintained at a temperature below which significant reaction occurs. Preferably, the precursor gas mixture is kept at a temperature below the thermal decomposition temperatures of the organohafnium compound and the olefinic hydrocarbon until deposition is desired.

The precursor gas mixture is delivered to a location adjacent the moving glass substrate. Prior to deposition, the substrate is at a temperature above the thermal decomposition temperature of the organohafnium compound in the precursor gas mixture. The precursor gas mixture is thereafter introduced into a vapor space above the substrate. The heat from the substrate raises the temperature of the precursor gas mixture above the thermal decomposition temperature of the organohafnium compound. The primary reactants then react with each other to produce a hafnium containing coating on the substrate.

The deposition rate is dependent upon the particular olefinic hydrocarbon used, the concentrations of both the olefinic hydrocarbon and the organohafnium compound, as well as the temperature of the glass substrate. In particular, the use of ethylene produces a particularly efficient reaction with the tetrakisdialkylamido hafnium compounds. The exact role of ethylene in the deposition of the hafnium-containing coating from organohafnium compounds has not been established. It will be appreciated that the use of higher concentrations of reactants and high gas flow rates is likely to result in a less efficient overall conversion of the reactants into a coating. Thus, the optimum conditions for commercial operation may differ from the conditions which provide the highest deposition rates.

The presently described subject matter permits the production, at high rates, of hafnium-containing coatings on moving hot flat glass substrates on-line during the float glass production process. For depositing a hafnium-containing coating, the moving glass substrate should be at a temperature of at least 400° C. when the precursor gas mixture is introduced into the vapor space above the moving glass substrate. Typically, for practicing the presently described subject matter the glass substrate temperature is in a range of about 450° C.-750° C. The more preferred substrate temperature is in the range of about 450° C.-700° C. Regardless of the temperature of the substrate during deposition, the hafnium-containing coatings produced in accordance with the presently described subject matter have been found to have a refractive index in the range of about 1.7 to about 1.9. This permits the achievement of desired optical effects, especially when used in combination with other coating layers. It should be noted that the refractive index values described herein are reported as an average value across 400-780 nm of the electromagnetic spectrum.

Where a float glass installation is utilized as a means for practicing the presently described subject matter, the float glass apparatus more particularly comprises a canal section along which molten glass is delivered from a melting furnace, to a float bath section wherein a continuous glass ribbon is formed by a float process. The glass ribbon advances from the bath section through an adjacent annealing lehr and a cooling section. The continuous glass ribbon serves as the substrate upon which the hafnium-containing coating is deposited in accordance with the presently described subject matter.

The bath section includes a bottom section within which a bath of molten tin is contained, a roof, opposite sidewalls, and end walls. It is understood that the bath may include other suitable materials to achieve the desired results. The roof, side walls, and end walls together define an enclosure in which a non-oxidizing atmosphere is maintained to prevent oxidation of the molten tin. Additionally, gas distributor beams may be located in the bath section. Gas distributor beams in the bath section may be employed to apply the hafnium-containing coating by the process of the presently described subject matter or additional coatings onto the substrate prior to applying the hafnium-containing coating. The additional coatings may include tin oxide and/or silicon dioxide, for example.

In operation, the molten glass flows along the canal beneath a regulating tweel and downwardly onto the surface of the tin bath in controlled amounts. On the tin bath the molten glass spreads laterally under the influences of gravity and surface tension, as well as certain mechanical influences, and it is advanced across the bath to form the ribbon. The ribbon is removed over lift out rolls and is thereafter conveyed through the annealing lehr and the cooling section on aligned rolls. Heaters may be provided within the annealing lehr for causing the temperature of the glass ribbon to be gradually reduced in accordance with a predetermined regime as it is conveyed therethrough. Also, typically ambient air may be directed against the glass ribbon as by fans in the cooling section.

The application of the hafnium-containing coating of the presently described subject matter may take place in the float bath section or further along the production line. For example, the hafnium-containing coating may be deposited in the gap between the float bath and the annealing lehr or in the annealing lehr itself.

For forming the coating in the bath section, a suitable non-oxidizing atmosphere, generally nitrogen or a mixture of nitrogen and hydrogen in which nitrogen predominates, is maintained to prevent oxidation of the molten tin. The atmosphere gas is admitted through conduits operably coupled to a distribution manifold. The non-oxidizing gas is introduced at a rate sufficient to compensate for normal losses and maintain a slight positive pressure, on the order of about 0.001 to about 0.01 atmospheres above ambient atmospheric pressure, so as to prevent infiltration of outside atmosphere. For purposes of the presently described subject matter the above-noted pressure range is considered to constitute normal atmospheric pressure. Heat for maintaining the desired temperature regime in the tin bath and the bath enclosure is provided by radiant heaters within the enclosure and the glass ribbon itself.

The atmosphere within the lehr is typically atmospheric air. However, when forming a hafnium-containing coating in the lehr, an inert atmosphere may be maintained in the lehr section where the deposition is to occur. Similarly, the atmosphere in the gap between the lehr and the bath is typically atmospheric air and the bath section atmosphere, however an inert atmosphere may be provided when depositing a hafnium-containing coating there also. In either scenario, the pressure of the inert atmosphere may be substantially similar to the pressure of the bath section atmosphere.

Gas distributor beams may be positioned in the bath section, the gap between the bath section and the annealing lehr, or in the annealing lehr to deposit the various coatings on the glass ribbon substrate. The gas distributor beam is one form of reactor that can be employed in practicing the process of the presently described subject matter.

A configuration for the distributor beams suitable for supplying the precursor materials in accordance with the presently described subject matter is an inverted, generally channel-shaped framework formed by spaced inner and outer walls and defining two enclosed cavities. A suitable heat exchange medium is circulated through the enclosed cavities in order to maintain the distributor beams at a desired temperature.

The precursor gas mixture is supplied through a supply conduit. Depending on the location of the deposition, the supply conduit may be surrounded by a cooling fluid. The supply conduit extends along the distributor beam and admits the precursor gas mixture through drop lines spaced along the supply conduit. The supply conduit leads to a delivery chamber within a header carried by the framework. The precursor gas mixture admitted through the drop lines is discharged from the delivery chamber through a passageway toward a coating chamber defining a vapor space opening onto the glass substrate where the precursor gas mixture flows along the surface of the substrate.

Baffle plates may be provided within the delivery chamber for equalizing the flow of the precursor gas mixture across the distributor beam to assure that the precursor gas mixture is discharged against the glass substrate in a smooth, laminar, uniform flow entirely across the distributor beam. Spent precursor gases are collected and removed through exhaust chambers along the sides of the distributor beam.

Various forms of distributor beams used for chemical vapor deposition are suitable for the present method and are known in the prior art. In one such alternative distributor beam configuration, the precursor gas mixture is introduced through a gas supply duct where it is cooled by cooling fluid circulated through a plurality of ducts. The gas supply duct opens through an elongated aperture into a glass flow restrictor.

The gas flow restrictor comprises a plurality of metal strips longitudinally crimped in the form of a sine wave and vertically mounted in abutting relationship with one another extending along the length of the distributor. Adjacent crimped metal strips are arranged “out of phase” to define a plurality of vertical channels between them. These vertical channels are of small cross-sectional area relative to the cross-sectional area of the gas supply duct, so that the precursor gas mixture is released from the gas flow restrictor at substantially constant pressure along the length of the distributor.

The precursor gas mixture is released from the gas flow restrictor into the inlet side of a substantially U-shaped guide channel generally comprising an inlet leg of a coating chamber which opens onto the glass substrate to be coated, and at least one exhaust leg, whereby used precursor gases are withdrawn from the glass. It is understood that the guide channel may have any suitable size, shape, and configuration as desired. The rounded corners of the blocks defining the coating channel promote a uniform laminar flow of coating parallel to the glass surface across the glass surface to be coated.

### EXAMPLES

The following examples (in which gas volumes are expressed under standard conditions, i.e., one atmosphere pressure and ambient temperature, unless otherwise stated) are for illustrative purposes only and are not to be construed as a limitation on the presently described subject matter.

The following experimental conditions are applicable to Comparative Examples 1-2, Examples 3-4 in Table 1, and Examples 5-12 in Table 2.

In Examples 1-12, the organohafnium compound utilized was tetrakisdimethyl amido hafnium. Preparation and containment of the organohafnium compound and ethyl acetate, EtOAc, was accomplished by utilizing multiple source chambers known as bubblers. There was one bubbler for each of the organohafnium compound and the EtOAc and each was maintained at a specific temperature. In Examples 1-12, the organohafnium compound bubbler was maintained at a temperature of approximately 100° C. In Examples 1-12, the EtOAc bubbler was maintained at a temperature of approximately 60° C. To deliver the precursor gas mixture, helium gas was introduced into a bubbler at the particular flow rate listed in Table 1.

At ambient temperature, oxygen and ethylene are gaseous. Thus, neither needs be contained and heated in a bubbler. However, it is preferable to preheat both prior to premixing either with the organohafnium compound. The amount of preheating is not critical but should be enough to raise the temperature of either to a temperature similar to that of the organohafnium compound.

The glass substrate was heated to the desired temperature and conveyed through a laboratory furnace. The laboratory furnace had a 25.4 cm wide bi-directional coater positioned above the glass substrate. The coater was suitable for distributing the gaseous reactants onto the surface of the glass substrate in order to form a coating layer or stack of layers by chemical vapor deposition.

Table 1 summarizes the deposition flow rates of the precursor gas mixtures delivered to the surface of the glass substrate in accordance with the presently described subject matter. The various reactants described below were premixed into a uniform precursor gas mixture prior to being introduced into the vapor space above the glass substrate. At the time the precursor gas mixture was introduced into the vapor space above the glass substrate, the substrate used in Example 1 was at a temperature of 454° C., the substrate used in Example 2 was at a temperature of 632° C., the substrate used in Example 3 was at a temperature of 632° C., and the substrate used in Example 4 was at a temperature of 632° C.

Examples 1-3 were conducted under static conditions using a soda-lime-silica glass substrate whereon a silicon dioxide layer 200 Angstroms thick had been previously deposited. Example 4 was conducted under dynamic conditions at a line speed of 75 inches per minute using a soda-lime-silica glass substrate whereon a silicon dioxide layer 200 Angstroms thick had been previously deposited.

TABLE 1
Glass Substrate/Silicon Dioxide/Hafnium Coating

| | | | Hf | | | |
|---|---|---|---|---|---|---|
| | Carrier 1 | Carrier 2 | (NMe₂)₄ | EtOAc | O₂ | C₂H₄ |
| Comparative | | | | | | |
| Example | | | | | | |
| 1 | 15 He | 15 He | 3 | 1 | 0 | 0 |
| 2 | 15 He | 15 He | 5 | 0 | 3 | 0 |
| Example | | | | | | |
| 3 | 15 He | 15 He | 5 | 0 | 3 | 5 |
| 4 | 15 He | 15 He | 5 | 0 | 3 | 5 |

Note: All flow rates are in standard liters per minute.

A hafnium-containing layer was not formed in Comparative Examples 1 and 2. In Example 3, a hafnium-containing layer was formed at a rate of 160 Angstroms per second. In Example 4, a hafnium-containing layer was formed at a rate of approximately 85 Angstroms per second. Hafnium-containing coating thicknesses were determined optically.

Table 2 summarizes the input parameters and coating properties for Examples 5-12 in accordance with the presently described subject matter. The various reactants described below were premixed into a uniform precursor gas mixture prior to being introduced into the vapor space above the glass substrate. Examples 5-12 were conducted under static conditions using a glass substrate. In addition to the input parameters shown in Table 2 for Examples 5-12, molecular oxygen (O₂) was also introduced. The source for the molecular oxygen for Examples 5-12 was the surrounding atmosphere.

TABLE 2
Glass Substrate/Silicon Dioxide/Hafnium Coating

| Input Parameters | | | | | Coating Properties | | |
|---|---|---|---|---|---|---|---|
| | Sub- | | Hf | | | Visible | Film |
| | strate | Glass | (NMe₂)₄ | | | Light | Side |
| | Temp. | Sub- | Precursor | C₂H₄ | Haze | Trans. | Refl. |
| Example | (° C.) | strate | (%) | (%) | (%) | (%) | (%) |
| 5 | 600 | Silica | 0.5 | 14 | 0.41 | 80.85 | 16.55 |
| | | Coated | | | | | |
| 6 | 600 | Silica | 0.3 | 6 | 0.42 | 88.15 | 10.55 |
| | | Coated | | | | | |
| 7 | 427 | Silica | 0.5 | 14 | 0.32 | 74.92 | 15.99 |
| | | Coated | | | | | |
| 8 | 427 | Silica | 0.3 | 6 | 0.29 | 86.71 | 11.35 |
| | | Coated | | | | | |
| 9 | 315 | Silica | 0.5 | 14 | 0.09 | 91.05 | 8.73 |
| | | Coated | | | | | |
| 10 | 510 | Silica | 0.5 | 14 | 0.28 | 56.32 | 21.46 |
| | | Coated | | | | | |
| 11 | 510 | Silica | 0.3 | 6 | 0.44 | 62.64 | 23.32 |
| | | Coated | | | | | |
| 12 | 510 | Un- | 0.5 | 14 | 0.54 | 59.11 | 19.59 |
| | | coated | | | | | |

The coating of Example 9, deposited at a lower substrate temperature, was not thick enough to be acceptable for most applications.

It will be noted that the process of the presently described subject matter may be repeated as desired on a given substrate so as to form a coating consisting of several successive layers, the composition of each layer not necessarily being identical. It is, of course, obvious that for a given flow rate of the reactants; the thickness of a coating layer depends on the rate of movement of the substrate. Under these conditions, the reaction stations may, if desired, be multiplied by juxtaposing two or more coating devices. In this way, successive layers are superimposed before the layers have had time to cool, producing a particularly homogeneous overall coating and/or coating stack.

In practicing the presently described subject matter, it may be preferable to apply a layer of a material which acts as a sodium diffusion barrier between the glass substrate and the hafnium-containing coating. For example, coated glass articles have been found to exhibit lower haze when the hafnium-containing coating deposited in accordance with the presently described subject matter is applied to a glass substrate with a sodium diffusion layer therebetween, as opposed to directly on the glass. This may be particularly true when the glass substrate is soda-lime-silica glass. Thus, in one embodiment, a sodium diffusion layer comprising silicon dioxide is formed over the surface of the glass substrate. In this embodiment, the layer of silicon dioxide, preferably formed using conventional CVD techniques, is preferably at least 200 Angstroms thick.

In another embodiment, a layer of tin oxide is first deposited over the surface of the glass substrate with a layer of silicon dioxide deposited thereover. The layer of tin oxide is deposited on and adheres to the surface of the glass substrate. This creates an underlayer structure of tin oxide/silicon dioxide formed intermediate the glass and the subsequently deposited layer of hafnium-containing coating. In this embodiment, the silicon dioxide film not only acts as a sodium diffusion barrier but, in combination with the first (undoped) tin oxide film, helps to suppress iridescence in the resulting coated glass article. The use of such anti-iridescent layers is disclosed in U.S. Pat. No. 4,377,613, which is incorporated herein in its entirety by reference thereto.

The presently described subject matter has been disclosed in what is considered to be its preferred embodiment. It must be understood, however, the specific embodiments are provided only for the purpose of illustration, and that the presently described subject matter may be practiced otherwise than as specifically illustrated without departing from its spirit and scope.

1-18. (canceled)

19. A method of forming a coated glass article, comprising:
providing a glass substrate; and
depositing a hafnium-containing coating on the glass substrate using a chemical vapor deposition process,
wherein the chemical vapor deposition process utilizes a precursor gas mixture comprising an organohafnium compound, molecular oxygen, and an olefinic hydrocarbon,
wherein the precursor gas mixture is introduced into a vapor space above the glass substrate,
wherein the organohafnium compound and the olefinic hydrocarbon react to produce the hafnium-containing coating on the glass substrate,
wherein the hafnium-containing coating exhibits a refractive index between about 1.7 and 1.9.

20. The method according to claim 19, wherein the organohafnium compound is a hafnium amido compound.

21. The method according to claim 20, wherein the hafnium amido compound comprises a tetrakisdialkylamido hafnium, Hf(NMe₂)_{4.}

22. The method according to claim 19, wherein the organohafnium compound comprises a tetrakisdialkylamido hafnium compound of a form Hf(NR¹R²)₄ where R¹ and R² are hydrocarbons having 1, 2, or 6 carbon atoms.

23. The method according to claim 19, wherein the hafnium-containing coating has a thickness of at least 50 Angstroms.

24. The method according to claim 19, wherein the precursor gas mixture further comprises helium.

25. The method according to claim 19, wherein a temperature of the glass substrate is at least 400° C., preferably 425° C., when the precursor gas mixture is introduced into the vapor space.

26. The method according to claim 19, wherein a temperature of the glass substrate is between 425° C. and 700° C., preferably between 450° C. and 700° C., when the precursor gas mixture is introduced into the vapor space.

27. The method according to claim 19, wherein the olefinic hydrocarbon is at least one of ethylene, propylene, and butene.

28. The method according to claim 19, wherein the olefinic hydrocarbon is ethylene.

29. The method according to claim 19, wherein the hafnium-containing coating is a hafnium oxide coating.

30. The method according to claim 19, wherein the glass substrate comprises soda-lime-silica glass.

31. The method according to claim 19, wherein the glass substrate is formed by a float glass process.

32. The method according to claim 19, wherein the hafnium-containing coating is deposited on the glass substrate at a deposition rate of at least 50 Angstroms per second.

33. The method according to claim 19, further comprising depositing a silicon dioxide layer between the glass substrate and the hafnium-containing coating.

34. The method according to claim 33, wherein the silicon dioxide layer has a thickness of at least 200 Angstroms.

35. The method according to claim 33, further comprising depositing a tin oxide layer between the glass substrate and the silicon dioxide layer.

36. A chemical vapor deposition process for depositing a coating on a moving glass substrate to form a coated glass article, comprising:
providing a uniform precursor gas mixture comprising an organohafnium compound, molecular oxygen, and an olefinic hydrocarbon, each of the organohafnium compound and the olefinic hydrocarbon having a respective thermal decomposition temperature;
delivering the precursor gas mixture at a temperature below the respective thermal decomposition temperatures of the organohafnium compound and the olefinic hydrocarbon to a location adjacent the moving glass substrate to be coated, the moving glass substrate being at a temperature above the thermal decomposition temperature of the organic hafnium compound and surrounded by an atmosphere having a pressure at about atmospheric pressure; and
introducing the precursor gas mixture into a vapor space above the moving glass substrate wherein the organohafnium compound and the olefinic hydrocarbon react to produce the coating on the glass substrate, wherein the coating is a hafnium hafnium-containing coating exhibiting a refractive index between about 1.7 and 1.9.

37. The chemical vapor deposition process according to claim 36, wherein the organohafnium compound comprises a tetrakisdialkylamido hafnium, Hf(NMe₂)₄.

38. The chemical vapor deposition process according to claim 36, wherein the organohafnium compound comprises a tetrakisdialkylamido hafnium compound of a form Hf(NR¹R²)₄ where R¹ and R² are hydrocarbons having 1, 2, or 6 carbon atoms.
